(19) United States
(12) Patent Application Publication
(10) Pub. No.: US 2026/0074168 A1
(43) Pub. Date: Mar. 12, 2026

(54) Method for Controlling Plasma Measuring System and Plasma Measuring System

(71) Applicant: TOKYO ELECTRON LIMITED, Tokyo (JP)

(72) Inventor: Mitsutoshi ASHIDA, Yamanashi (JP)

(21) Appl. No.: 19/315,176

(22) Filed: Aug. 29, 2025

(30) Foreign Application Priority Data
Sep. 9, 2024 (JP) 2024-155304

(51) Int. Cl. H01J 37/32; G01R 19/00

(52) U.S. Cl. CPC H01J 37/32917; G01R 19/0046; H01J 2237/24564

(57) ABSTRACT

There is a method for controlling a plasma measuring system that measures a state of plasma using a probe device provided in a plasma processing apparatus and a measuring circuit including a signal generator that outputs an AC voltage, the method comprising: (A) outputting a fundamental wave voltage from the signal generator to the plasma to be measured; (B) detecting an output terminal AC voltage at an output terminal of the signal generator; and (C) superimposing a voltage of a harmonic voltage component, which reduces an amplitude of the harmonic voltage component contained in the output terminal AC voltage, on the fundamental wave voltage, and outputting the superimposed voltage from the signal generator.

### CROSS-REFERENCE TO RELATED APPLICATIONS

This application claims priority to Japanese Patent Application No. 2024-155304 filed on Sep. 9, 2024, the entire contents of which are incorporated herein by reference.

### TECHNICAL FIELD

The present disclosure relates to a method for controlling a plasma measuring system, and a plasma measuring system.

### BACKGROUND

Japanese Laid-open Patent Publication No. 2019-46787 discloses a plasma probe device including an antenna part attached to an opening formed in a wall of a processing chamber or a placing table via a sealing member that seals a gap between a vacuum space and an atmospheric space, an electrode connected to the antenna part, and a dielectric support part made of a dielectric and configured to support the antenna part from a periphery side thereof. The antenna part and a facing surface of the wall or the placing table are separated by a predetermined width, and a surface of the antenna part exposed from the opening is recessed from a surface of the wall or the placing table on a plasma generation side where the opening is formed.

### SUMMARY

In one aspect, the present disclosure provides a method for controlling a plasma measuring system for measuring a state of plasma, and a plasma measuring system.

In accordance with an exemplary embodiment of the present disclosure, there is a method for controlling a plasma measuring system that measures a state of plasma using a probe device provided in a plasma processing apparatus and a measuring circuit including a signal generator that outputs an AC voltage, the method comprising: (A) outputting a fundamental wave voltage from the signal generator to the plasma to be measured; (B) detecting an output terminal AC voltage at an output terminal of the signal generator; and (C) superimposing a voltage of a harmonic voltage component, which reduces an amplitude of the harmonic voltage component contained in the output terminal AC voltage, on the fundamental wave voltage, and outputting the superimposed voltage from the signal generator

### BRIEF DESCRIPTION OF THE DRAWINGS

FIG. 1 is a schematic cross-sectional view showing an example of a plasma processing apparatus according to one embodiment.

FIG. 2 is a diagram showing an example of the II-II cross section of FIG. 1.

FIG. 3 is a diagram showing an example of a functional configuration of a measurement system and a controller according to an embodiment.

FIG. 4 is a flowchart showing an example of a method for controlling a plasma processing apparatus.

FIGS. 5A and 5B are graphs showing an example of a received signal received from a plasma side.

FIG. 6 is a diagram showing an example of a circuit model of a measurement system.

FIG. 7 is a diagram showing an example of a circuit model of the measurement system including a parasitic capacitance.

FIGS. 8A and 8B are diagrams showing examples of vector diagrams showing a current vector and a voltage vectors, respectively.

FIG. 9 is a diagram showing an example of a circuit model of the measurement system for a second harmonic wave.

FIGS. 10A and 10B are diagrams showing examples of vector diagrams showing a current vector and a voltage vector, respectively.

FIGS. 11A and 11B are diagrams showing an example of a voltage vector.

FIGS. 12A to 12C are diagrams showing an example of feedback control.

FIG. 13 is a flowchart showing another example of the feedback control.

### DETAILED DESCRIPTION

Hereinafter, embodiments of the present disclosure will be described in detail with reference to the accompanying drawings. Like reference numerals will be given to like parts throughout the drawings, and redundant description thereof may be omitted.

### (Plasma Processing Apparatus)

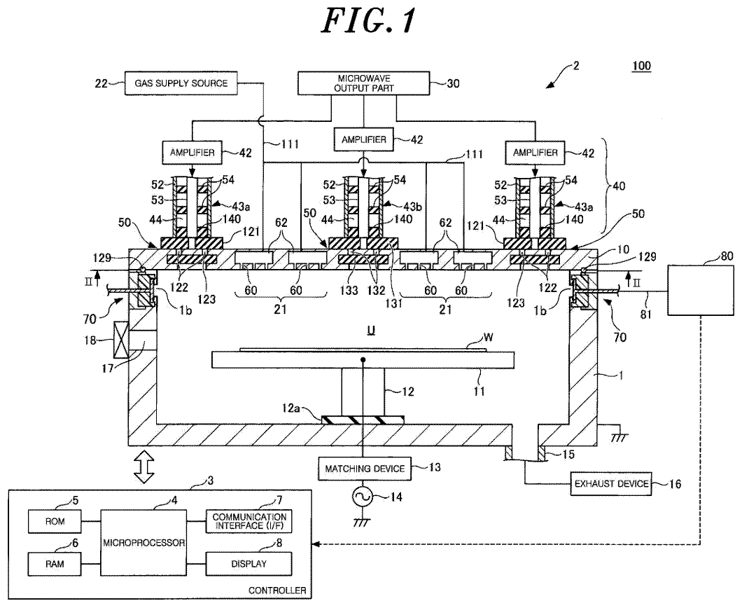

FIG. 1 shows an example of a cross-sectional view of a plasma processing apparatus 100 according to an embodiment of the present disclosure. The plasma processing apparatus 100 has a processing chamber 1 that accommodates a substrate W that is an example of a semiconductor wafer. The plasma processing apparatus 100 is an example of a plasma processing apparatus that performs plasma processing on the substrate W by surface wave plasma generated on a bottom surface of a ceiling wall 10 of the processing chamber 1 by microwaves. The plasma processing may include film formation, etching, and ashing using plasma.

The plasma processing apparatus 100 includes the processing chamber 1, a microwave plasma source 2, and a controller 3. The processing chamber 1 is an airtight substantially cylindrical chamber made of a metal material such as aluminum or stainless steel. The processing chamber 1 is grounded.

The processing chamber 1 has the ceiling wall 10, and forms therein a space (plasma generation space U) for performing plasma processing on the substrate W. The ceiling wall 10 is a lid that is formed in a disc shape and closes the upper opening of the processing chamber 1. A support ring 129 is provided at the contact surface between the processing chamber 1 and the ceiling wall 10, thereby hermetically sealing the inside of the processing chamber 1. The ceiling wall 10 is made of a metal material such as aluminum or stainless steel.

The microwave plasma source 2 has a microwave output part 30, a microwave transmission part 40, and a microwave radiation mechanism 50. The microwave output part 30 outputs microwaves by distributing them to a plurality of paths. The microwaves are introduced into the processing chamber 1 through the microwave transmission part 40 and the microwave radiation mechanism 50. The gas supplied into the processing chamber 1 is excited by the electric field of the introduced microwaves, thereby generating surface wave plasma.

A placing table 11 for placing the substrate W is provided in the processing chamber 1. The placing table 11 is supported by a cylindrical support member 12 standing upright at the center of the bottom portion of the processing chamber 1 via an insulating member 12a. The materials forming the placing table 11 and the support member 12 include a metal such as aluminum having an alumite-treated (anodically oxidized) surface, or an insulating member (ceramic or the like) having therein a high-frequency electrode. The placing table 11 may be provided with an electrostatic chuck for electrostatically attracting the substrate W, a temperature control mechanism, a gas channel for supplying a heat transfer gas to the backside of the substrate W, or the like.

A high-frequency bias power supply 14 is connected to the placing table 11 via a matching device 13. When a high-frequency power is supplied from the high-frequency bias power supply 14 to the placing table 11, ions in the plasma are attracted toward the substrate W. Further, the high-frequency bias power supply 14 may not be provided depending on the characteristics of the plasma processing.

An exhaust line 15 is connected to the bottom portion of the processing chamber 1, and an exhaust device 16 including a vacuum pump is connected to the exhaust line 15. When the exhaust device 16 operates, the inside of the processing chamber 1 is exhausted and, thus, a pressure in the processing chamber 1 is quickly depressurized to a predetermined vacuum level. A loading/unloading port 17 for loading/unloading the substrate W and a gate valve 18 for opening/closing the loading/unloading port 17 are provided on the sidewall of the processing chamber 1.

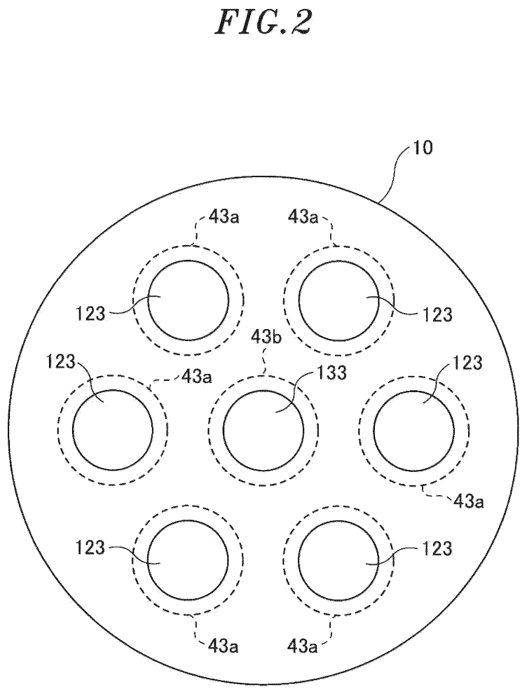

The microwave transmission part 40 transmits microwaves outputted from the microwave output part 30. FIG. 2 shows a cross section taken along line II-II in FIG. 1, and illustrates an example of the bottom surface of the ceiling wall of the plasma processing apparatus 100. Referring to FIG. 2, a central microwave introducing part 43b in the microwave transmission part 40 is located at the center of the ceiling wall 10, and six peripheral microwave introducing parts 43a are located at equal intervals in the circumferential direction at the periphery of the ceiling wall 10. The central microwave introducing part 43b and the six peripheral microwave introducing parts 43a have the function of introducing the microwaves outputted from corresponding amplifier 42 shown in FIG. 1 to the microwave radiation mechanism 50 and the function of matching an impedance. Hereinafter, the peripheral microwave introducing parts 43a and the central microwave introducing part 43b are collectively referred to as the microwave introducing part 43.

As shown in FIGS. 1 and 2, six dielectric windows 123 on the outer peripheral side are located inside the ceiling wall 10 under the six peripheral microwave introducing parts 43a. Further, a central dielectric window 133 is located inside the ceiling wall 10 under the central microwave introducing part 43b. Further, the number of the peripheral microwave introducing parts 43a and the number of the dielectric windows 123 are not limited to six, and may be two or more. However, the number of the peripheral microwave introducing parts 43a is preferably three or more, and may be three to six, for example.

The microwave radiation mechanism 50 shown in FIG. 1 includes wave retardation plates 121 and 131, slots 122 and 132, and dielectric windows 123 and 133. The wave retardation plates 121 and 131 are made of a disc-shaped dielectric material that transmits microwaves, and are located on the upper surface of the ceiling wall 10. The wave retardation plates 121 and 131 are made of ceramic such as quartz or alumina (Al₂O₃), fluorine-based resin such as polytetrafluoroethylene, or polyimide-based resin, which have a relative dielectric constant greater than that of vacuum. Accordingly, the wave retardation plates 121 and 131 have a function of reducing a size of the antenna including the slots 122 and 132 by making the wavelength of the microwaves transmitted through the wave retardation members 121 and 131 shorter than the wavelength of the microwaves propagating in vacuum.

Under the wave retardation plates 121 and 131, the dielectric windows 123 and 133 are in contact with the back surface of the opening in the ceiling wall 10 via the slots 122 and 132 formed in the ceiling wall 10. The dielectric windows 123 and 133 are made of, for example, ceramic such as quartz or alumina (Al₂O₃), fluorine-based resin such as polytetrafluoroethylene, or polyimide-based resin. The dielectric windows 123 and 133 are located at positions recessed from the ceiling surface by the thickness of the opening formed in the ceiling wall 10, and are configured to supply microwaves to the plasma generation space U.

In the peripheral microwave introducing part 43a and the central microwave introducing part 43b, a cylindrical outer conductor 52 and a rod-shaped inner conductor 53 provided at the center of the cylindrical outer conductor 52 are coaxially arranged. A microwave power is supplied to the gap between the outer conductor 52 and the inner conductor 53, and the gap therebetween serves as a microwave transmission path 44 through which microwaves propagate toward the microwave radiation mechanism 50.

Each of the peripheral microwave introducing part 43a and the central microwave introducing part 43b is provided with a slug 54 and an impedance adjusting member 140 located at the tip end of the slug 54. The impedance adjusting member 140 has a function of matching an impedance of a load (plasma) in the processing chamber 1 with a characteristic impedance of a microwave power source in the microwave output part 30 by moving the slug 54. The impedance adjusting member 140 is made of a dielectric material, and is configured to adjust the impedance of the microwave transmission path 44 based on its relative dielectric constant.

The ceiling wall 10 is provided with a gas introducing part 21 having a shower structure. A gas supplied from a gas supply source 22 reaches the gas diffusion space 62 through a gas supply line 111, and is supplied into the processing chamber 1 in a shower pattern through the gas introducing part 21. The gas introducing part 21 is an example of a gas shower head for supplying a gas from a plurality of gas supply holes 60 formed in the ceiling wall 10. The gas may be a gas for plasma generation, such as Ar gas, a gas to be decomposed with high energy, such as O₂ gas or N₂ gas, a processing gas such as silane gas, or the like.

Individual components of the plasma processing apparatus 100 are controlled by the controller 3. The controller 3 includes a microprocessor 4, a read only memory (ROM) 5, and a random access memory (RAM) 6. A process sequence of the plasma processing apparatus 100 and a process recipe that is a control parameter are stored in the ROM 5 or the RAM 6. The microprocessor 4 controls the individual components of the plasma processing apparatus 100 based on the process sequence and the process recipe. Further, the controller 3 has a communication interface (I/F) 7, and can communicate with other devices. Further, the controller 3 has a display 8, and can display results at the time of performing predetermined control based on the process sequence and the process recipe.

In the case of performing plasma processing in the plasma processing apparatus 100 configured as described above, first, the substrate W is held on a transfer arm (not shown) and transferred into the processing chamber 1 from the open gate valve 18 through the loading/unloading port 17. When the substrate W is transferred to a position above the placing table 11, the substrate W is transferred from the transfer arm to a pusher pin(s), and is placed on the placing table 11 by lowering the pusher pin(s). The gate valve 18 is closed after the substrate W is loaded. The pressure in the processing chamber 1 is maintained at a predetermined vacuum level by the exhaust device 16. The processing gas is introduced into the processing chamber 1 from the gas introducing part 21 in a shower pattern. The microwaves emitted from the microwave radiation mechanism 50 via the microwave introducing part 43 propagate along the vicinity of the bottom surface that is the inner surface of the ceiling wall. The gas is excited by the electric field of the surface-wave microwave, and the substrate W is subjected to plasma processing by the surface wave plasma generated in the plasma generation space U under the ceiling wall inside the processing chamber 1.

### (Probe Device)

The description of the probe device 70 will be continued with reference to FIGS. 1 and 3. FIG. 3 shows an example of a functional configuration of a measurement system and a controller according to an embodiment. As shown in FIG. 1, one or multiple openings 1b are formed in the sidewall of the processing chamber 1 in the circumferential direction, and one or multiple probe devices 70 are installed via a sealing member (not shown) for sealing the gap between a vacuum space and an atmospheric space.

A gap with a predetermined width is formed between the tip end surface of the probe device 70 and the back surface near the opening 1b formed in the wall of the processing chamber 1. The gap is designed to be wide enough to prevent the probe device 70 from being connected to the wall of the processing chamber 1 in a DC manner, and narrow enough to prevent plasma or a gas from entering the gap. Alternatively, the probe device 70 may be installed at the opening formed in the placing table via a sealing member.

As shown in FIG. 3, the measurement system for measuring a plasma state includes the probe device 70 and a measuring circuit 85. The measuring circuit 85 has a monitor device 80, a blocking capacitor 72, and a coaxial cable 81. The monitor device 80 is connected to the controller 3 to be able to communicate therewith.

The probe device 70 is connected to the monitor device 80 via the coaxial cable 81 outside the plasma processing apparatus 100. The monitor device 80 has a signal generator 82, and the signal generator 82 outputs an AC voltage signal of a predetermined frequency to the coaxial cable 81. The AC voltage signal is transmitted through the coaxial cable 81, and the AC voltage is applied to the probe device 70. The blocking capacitor 72 is connected to the coaxial cable 81, transmits the AC voltage signal to the probe device 70, and blocks the DC voltage signal. As a result, the monitor device 80 receives only the AC voltage signal from the plasma side.

The probe device 70 senses plasma generated in the plasma generation space U. The probe device 70 detects a current signal flowing to the plasma side in response to a signal transmitted to the plasma side, and transmits it to the monitor device 80. The current signal flowing to the plasma side is transmitted from the monitor device 80 to the controller 3, and is received by the communication part 32 of the controller 3. The current value of the received signal is stored in a storage part 31. An analysis part 34 of a control part 33 performs fast Fourier transform (FFT) analysis on the current value of the received signal. A calculation part 35 of the control part 33 calculates a plasma electron temperature Tₑ or a plasma electron density Nᵢ based on the analysis result. Hence, the plasma state can be estimated accurately. As described above, the plasma measuring system for measuring the plasma state includes the probe device 70, the measuring circuit 85, and the controller 3 (the control part 33).

The storage part 31 is realized by the RAM 6 shown in FIG. 1. The communication part 32 is realized by a communication interface 7. The analysis part 34 and the calculation part 35 of the control part 33 are realized by the microprocessor 4.

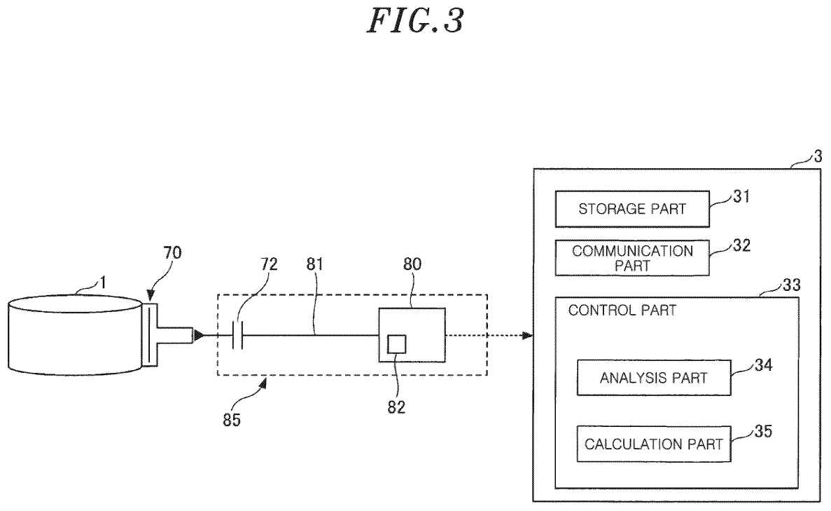

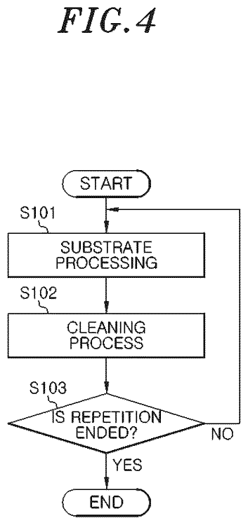

FIG. 4 is a flowchart showing an example of a method for controlling the plasma processing apparatus 100.

In step S101, the substrate processing is performed. Here, the controller 3 controls the gas supply source 22 to supply a processing gas (film forming gas, etching gas, or the like) from the gas supply holes 60 to the plasma generation space U, and controls the microwave output part 30 and the high frequency bias power supply 14 to generate plasma of the processing gas in the plasma generation space U, thereby performing desired processing (film formation, etching, or the like) on the substrate W. In this case, an AC voltage is applied from the signal generator 82 to the probe device 70, and the probe device 70 senses the plasma generated in the plasma generation space U. Then, the control part 33 calculates the plasma electron temperature Tₑ and the plasma electron density Nᵢ to estimate the plasma state.

Here, if the substrate processing is a process for forming an insulating film on the substrate W, an insulator (e.g., SiN, SiO₂, or the like) is deposited on the surface (the tip end surface of the probe device 70, or the like) of the probe device 70 exposed to the plasma generation space U to form an insulating film. The substrate processing is not limited to the formation of the insulating film, and may be processing (e.g., etching) in which an insulator is formed as reaction products, and the reaction products (insulator) are deposited on the surface exposed to the plasma generation space U of the probe device 70 to form the insulating film.

In step S101, the substrate processing is repeated until cleaning start conditions such as a predetermined number of processed substrates and processing time are satisfied. When the predetermined cleaning start conditions are satisfied, the processing of the controller 3 proceeds to step S102.

In step S102, a cleaning process (dry cleaning process: a cleaning process using a cleaning gas without exposing the processing container to the atmosphere) is performed. Here, the controller 3 controls the gas supply source 22 to supply a cleaning gas (e.g., NF₃ or the like) containing fluorine (F) from the gas supply holes 60 to the plasma generation space U, and controls the microwave output part 30 and/or the high frequency bias power supply 14 to generate plasma of the cleaning gas in the plasma generation space U, thereby removing the insulating film deposited in the processing chamber 1. In addition, the insulating film deposited on the surface exposed to the plasma generation space U of the probe device 70 is also removed.

Here, in the cleaning process, conductive fluoride is adhered to and accumulated on the surface of the probe device 70 exposed to the plasma generation space U, thereby forming a conductive deposition film. The conductive fluoride is, for example, a metal fluoride (e.g., AlF) containing a metal (e.g., Al) derived from the inner wall of the processing chamber 1 and the dielectric window 123, 133 made of alumina (Al₂O₃), and fluorine (F) derived from the cleaning gas. The deposited metal fluoride has lattice defects, and thus is conductive.

In step S103, it is determined whether or not to end the repetition. If the repetition is not ended (S103, NO), the process of the controller 3 returns to step S101, and the substrate processing and the cleaning process are repeated. If the repetition is ended (S103, YES), the process of the controller 3 is ended. In addition, a cleaning process (wet cleaning: a cleaning process in which the processing chamber is exposed to the atmosphere) and the like are performed.

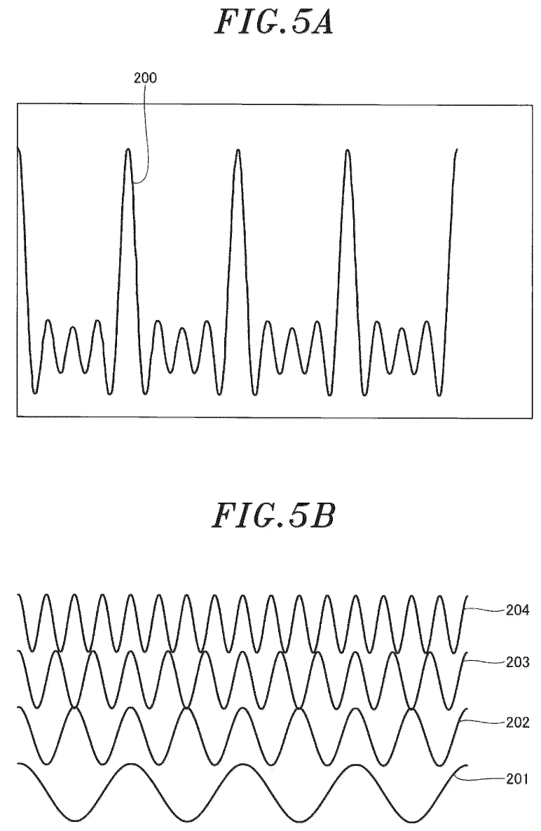

Here, an example of the measurement of the plasma state will be described. FIG. 5 is a graph showing an example of a received signal received from the plasma side.

FIG. 5A is a graph showing an example of raw data of a received signal detected by the probe device 70 and received by the monitor device 80. The horizontal axis represents time, and the vertical axis represents the strength (current value) of the received signal. As shown in FIG. 5A, the monitor device 80 receives a received signal 200 from the probe device 70.

FIG. 5B is a graph showing an example of the analysis result of the analysis part 34 of the control part 33. The analysis part 34 performs FFT (Fast Fourier Transform) analysis on the current value of the received signal 200. Accordingly, the received signal 200 is decomposed into frequency components such as a fundamental wave component (first harmonic wave component) 201, a second harmonic wave component 202, a third harmonic wave component 203, and a fourth harmonic wave component 204. Further, the calculation part 35 of the control part 33 calculates the plasma electron temperature Tₑ and the plasma ion density nᵢ based on the FFT analysis result. Accordingly, the plasma state is measured. Further, the plasma electron temperature Tₑ and the plasma ion density nᵢ are calculated based on the fundamental wave component 201 and the second harmonic component 202, as will be described later.

### (Method for Measuring Plasma State)

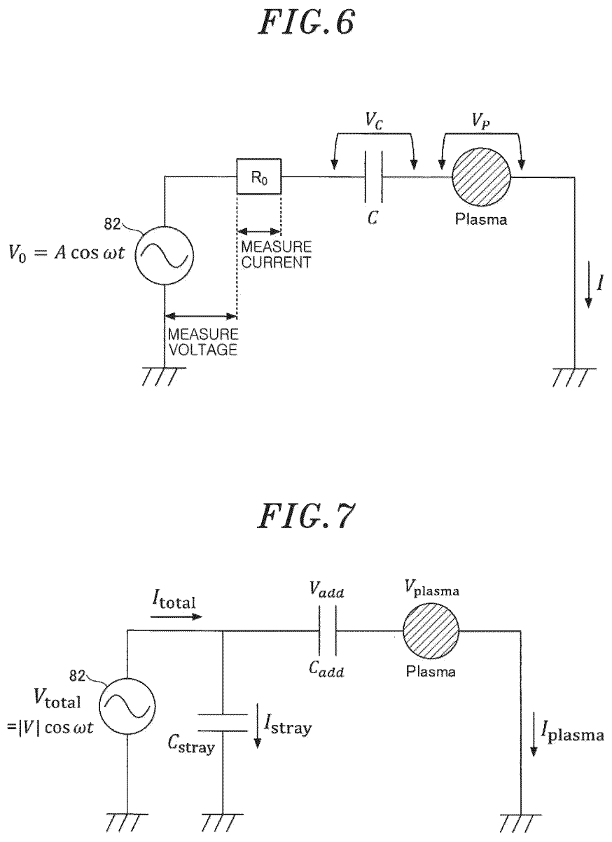

Next, the method for measuring the plasma electron temperature Tₑ and the plasma ion density nᵢ will be described with reference to FIG. 6. FIG. 6 shows an example of a circuit model of the measurement system.

As shown in FIG. 6, the insulating film is deposited on the probe device 70, resulting in a capacitance component C. The voltage across the insulating film (capacitance component C) is defined as V_{c}, and the voltage of the plasma is defined as Vₚ. Further, the monitor device 80 has a voltage measuring part (not shown) that measures a voltage (output terminal AC voltage) supplied to the plasma at the output terminal of the signal generator 82, and a current measuring part (not shown) that measures a current. R₀ is a resistor for measuring the current. The resistance value of R₀ is known, and is sufficiently small compared to the resistance value of the plasma. The current supplied to the plasma is measured by measuring a voltage across both ends of R₀.

Here, the plasma is assumed to be a pure resistance (with a phase difference) 0°, and the insulating film has the capacitance component C with a phase difference of 90°, so that it is possible to separately estimate the thickness of the insulating film (the capacitance component C) and the plasma state (the plasma electron temperature Tₑ and the plasma ion density nᵢ).

The current I flowing through the circuit model can be expressed by the following equation using the plasma voltage Vₚ. Iᵢₛ is an ion saturation current, Iₑₛ is an electron saturation current, V_{f} is a floating voltage, φₚ is a plasma voltage, Tₑ is a plasma electron temperature (eV), nₑ is a plasma electron density, nᵢ is a plasma ion density, S is a probe area, Mᵢ is an ion mass (kg), and mₑ is an electron mass (kg).

$$I = f ( {V}_{p} ) \qquad [ Eq . ( 1 ) ]$$

$$f ( V ) = {I}_{e s} exp ( \frac{{V}_{f} - {ϕ}_{p}}{{T}_{e}} ) exp ( \frac{V}{{T}_{e}} ) - {I}_{i s}$$

$${I}_{i s} = exp ( - \frac{1}{2} ) e {n}_{i} S \sqrt{\frac{e {T}_{e}}{{M}_{i}}}$$

$${I}_{e s} = \frac{1}{4} e {n}_{e} S \sqrt{\frac{8 e {T}_{e}}{π {m}_{e}}}$$

Next, it is assumed that Vₚ=V₀=Acosωt. A indicates an amplitude of an AC voltage outputted by the signal generator 82. The equation for the current I flowing through the circuit model described above is transformed using the first type modified Bessel function Iₖ(x). Accordingly, the equation for the current I is decomposed into frequency components.

$$\begin{matrix}I = {I}_{e s} exp ( \frac{{V}_{f} - {ϕ}_{p}}{{T}_{e}} ) exp ( \frac{{V}_{0} cos ω t}{{T}_{e}} ) - {I}_{is} \\ = {I}_{i s} exp ( \frac{{V}_{f} - {ϕ}_{p}}{{T}_{e}} ) {I}_{0} ( \frac{{V}_{0}}{{T}_{e}} ) - \\ {I}_{e s} + 2 {I}_{es} exp ( \frac{{V}_{f} - {ϕ}_{p}}{{T}_{e}} ) {\sum }_{k = 1}^{∞} {I}_{k} ( \frac{{V}_{0}}{{T}_{e}} ) cos ( k ω t )\end{matrix} \qquad [ Eq . ( 2 ) ]$$

Here, the information on the plasma electron density nₑ is contained only in the coefficients Iₑₛ of each frequency component. Therefore, the plasma electron density nₑ is deleted from the equation by dividing the fundamental current i_{1ω} by the second harmonic wave current i_{2ω}.

$$\frac{{i}_{1 ω}}{{i}_{2 ω}} = \frac{{I}_{1} ( \frac{{V}_{0}}{{T}_{e}} )}{{I}_{2} ( \frac{{V}_{0}}{{T}_{e}} )} \qquad [ Eq . ( 3 ) ]$$

The plasma electron temperature Tₑ is calculated from the above equation.

Further, the plasma ion density nᵢ can be expressed by the following equation. The plasma ion density nᵢ can be calculated using the following equation, the calculated plasma electron temperature Tₑ, and the fundamental current i_{1ω}.

$${n}_{i} = \frac{{i}_{1 ω}}{2 exp ( - \frac{1}{2} ) eS \sqrt{\frac{{eT}_{e}}{{M}_{i}}}} \frac{{I}_{0} ( \frac{{V}_{0}}{{T}_{e}} )}{{I}_{1} ( \frac{{V}_{0}}{{T}_{e}} )} \qquad [ Eq . ( 4 ) ]$$

### (Method for Measuring Plasma State in Consideration of Parasitic Capacitance)

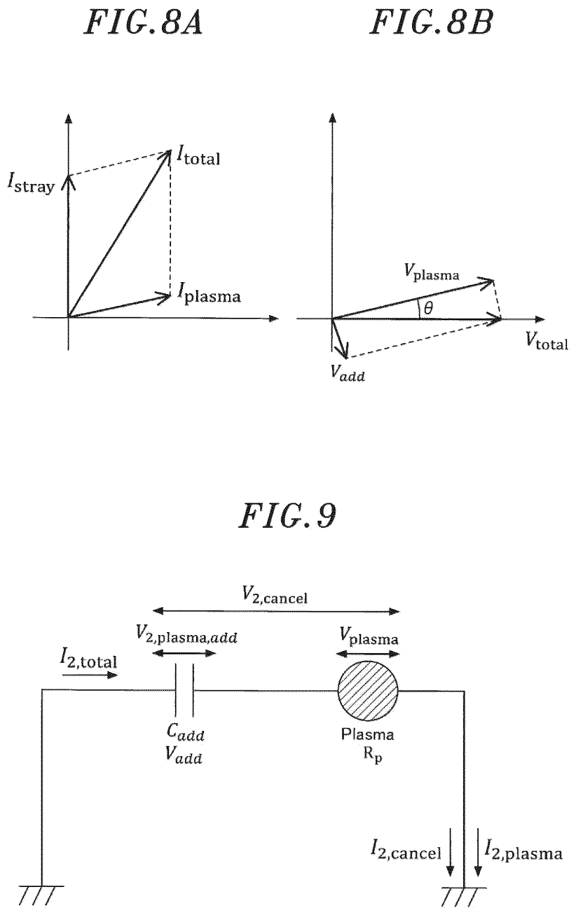

FIG. 7 is an example of a circuit model of a measurement system including parasitic capacitance (floating capacitance). FIGS. 8A and 8B are examples of vector diagrams showing a current vector and a voltage vector, respectively.

A voltage Vₜₒₜₐₗ is a voltage measured by the voltage measuring part (not shown) of the monitor device 80. A current Iₜₒₜₐₗ is a current measured by the current measuring part (not shown) of the monitor device 80. A voltage Vₚₗₐₛₘₐ is a plasma voltage. A current Iₚₗₐₛₘₐ is a plasma current. The voltage Vₚₗₐₛₘₐ and the current Iₚₗₐₛₘₐ are used at the time of measuring the plasma state (the plasma electron temperature Tₑ and the plasma ion density nᵢ).

Here, the circuit includes a series capacitance C_{add} in series with the signal generator 82, and a parasitic capacitance C_{stray} in parallel with the signal generator 82. Thus, a difference occurs between the voltage Vₚₗₐₛₘₐ and the current Iₚₗₐₛₘₐ of the plasma that are used at the time of measuring the plasma state (the plasma electron temperature Tₑ and the plasma ion density nᵢ) and the voltage Vₜₒₜₐₗ and the current Iₜₒₜₐₗ measured by the monitor device 80.

In the parasitic capacitance C_{stray} in parallel with the signal generator 82, a component that escapes to the ground voltage GND from the capacitance existing on the circuit such as the coaxial cable 81 or the like is dominant. Hence, it is generated regardless of the presence/absence of plasma. Therefore, in the extinguished state of plasma, the current I_{stray} is measured from the current Iₜₒₜₐₗ measured by the current measuring part (not shown) of the monitor device 80.

In the ignited state of plasma, as shown in FIG. 8A, the current Iₜₒₜₐₗ is expressed as the vector sum of the current Iₚₗₐₛₘₐ and the current I_{stray}. Therefore, the current vector of the plasma current Iₚₗₐₛₘₐ can be calculated by calculating the current vector difference obtained by subtracting the current vector of the current I_{stray} measured in advance from the current vector of the current Iₜₒₜₐₗ measured by the current measuring part (not shown) of the monitor device 80.

A series capacitance C_{add} in series with the signal generator 82 represents the series capacitance component such as the capacitor for insulation in the probe device 70 and the insulating film (SiN or the like) formed by deposits. When the current Iₚₗₐₛₘₐ flows, a voltage V_{add}, that lags the current Iₚₗₐₛₘₐ by 90 degrees, is generated. The effect of the parallel parasitic capacitance C_{stray} on the plasma is assumed to be sufficiently small. Further, the voltage Vₚₗₐₛₘₐ and the current Iₚₗₐₛₘₐ of the plasma are assumed to be in phase with each other.

A shown in FIG. 8B, the voltage Vₜₒₜₐₗ is expressed as the vector sum of the voltage Vₚₗₐₛₘₐ and the voltage V_{add}. Therefore, the voltage Vₚₗₐₛₘₐ can be calculated by using the phase difference θ between the voltage Vₚₗₐₛₘₐ and the voltage Vₜₒₜₐₗ as follows: voltage Vₚₗₐₛₘₐ=Vₜₒₜₐₗ×cos θ.

In this manner, the calculation part 35 can accurately calculate the voltage Vₚₗₐₛₘₐ and the current Iₚₗₐₛₘₐ of the plasma from the measured voltage Vₜₒₜₐₗ and current Iₜₒₜₐₗ by correcting (calibrating) the difference due to the series capacitance C_{add} and the parasitic capacitance C_{stray}. Accordingly, the plasma state (the plasma electron temperature Tₑ and the plasma ion density nᵢ) can be measured with high accuracy.

### (Second Harmonic Wave Current)

A high-order voltages are generated across the capacitor inserted into the circuit model of the measurement system by a nonlinear current generated by the plasma. As a result, high-order currents are superimposed on the plasma (see FIG. 5). Similarly to the case of the fundamental wave (first harmonic wave) described with reference to FIGS. 7 and 8, the vector of the total high-order current is orthogonal to the vector of the generated high-order current and, thus, this component can be corrected (calibrated) by measuring the phase between the fundamental wave current and the second harmonic wave current.

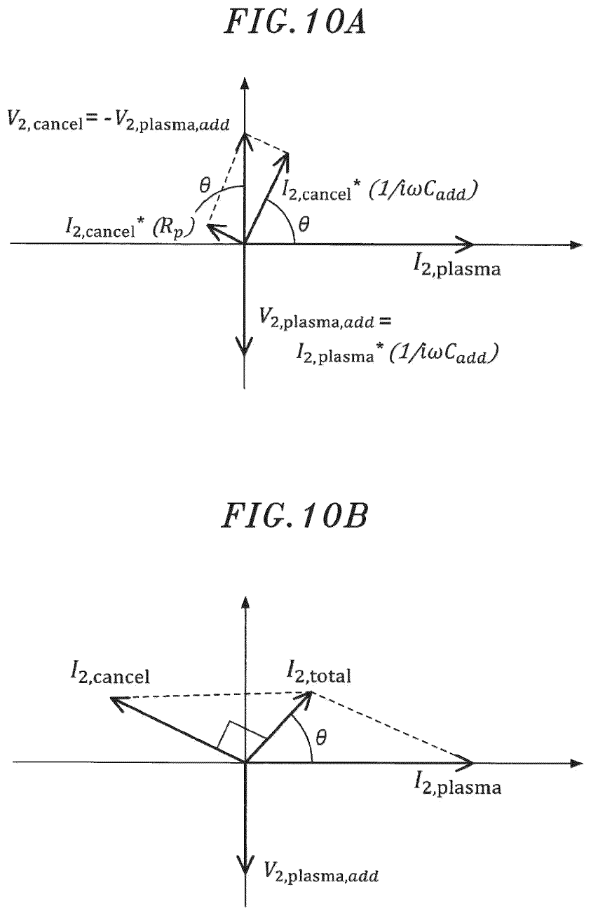

Hereinafter, the second harmonic wave current will be described. FIG. 9 is an example of a circuit model of a measurement system for a second harmonic wave. FIGS. 10A and 10B are examples of a vector diagram showing a current vector and a voltage vector, respectively.

The voltage Vₚₗₐₛₘₐ is a voltage obtained by dividing the voltage Vₜₒₜₐₗ (see FIG. 7) into the voltage V_{add} and the voltage Vₚₗₐₛₘₐ. However, the voltage Vₚₗₐₛₘₐ is only the fundamental wave voltage. In other words, the signal generator 82 outputs a fundamental wave voltage. Therefore, the circuit model of the measurement system for the second harmonic wave shown in FIG. 9 does not have the signal generator 82.

A voltage V_{2,plasma} is a second harmonic wave voltage applied to the plasma that is required to cause a current I_{2,cancel} to be described later to flow through the plasma.

A current I_{2,plasma} is a second harmonic wave current that is generated by applying the voltage Vₚₗₐₛₘₐ to the plasma. This current is generated because the current response in the plasma is nonlinear.

A voltage V_{2,plasma,add} is a second harmonic wave current that is generated by the current I_{2,plasma} flowing through the series capacitance C_{add}. The voltage V_{2,plasma,add} can be expressed by the following equation.

$${V}_{2 , plasme , add} = {I}_{2 , plasma} \times ( 1 / i ω {C}_{add} )$$

A voltage V_{2,cancel} is a voltage generated by the second harmonic wave current I_{2,cancel} that newly flows to cancel the voltage V_{2,plasma,add} required by Kirchhoff's law. The voltage V_{2,cancel} can be expressed by the following equation.

$${V}_{2 , cancel} = - {V}_{2 , plasma , add}$$

The current I_{2,cancel} is a second harmonic wave current that flows to generate the voltage V_{2,cancel}. The current I_{2,cancel} can be expressed by the following equation. Here, Rₚ denotes the pure resistance of the plasma. The current I_{2,cancel} also flows through the series capacitance C_{add}, so that a voltage is also generated thereacross.

$${I}_{2 , cancel} = {V}_{2 , cancel} / ( 1 / i ω {C}_{a d d} + {R}_{P} ) = - {I}_{2 , plasma} \times ( 1 / i ω {C}_{add} ) / ( 1 / i ω {C}_{a d d} + {R}_{P} )$$

A current I_{2,total} is the amount of the second harmonic wave current flowing through the entire circuit, and is the sum of the current I_{2,plasma} and the current I_{2,cancel}. In other words, current I_{2,total} can be expressed by the following equation.

$${I}_{2 , total} = {I}_{2 , plamsa} + {I}_{2 , cancel} = {I}_{2 , plasma} \times ( {R}_{P} ) / ( 1 / i ω {C}_{a d d} + {R}_{P} )$$

Here, the current I_{2,total} corresponds to the real part when the current I_{2,plasma} is expressed in complex space, and thus can be expressed by the following equation.

$${I}_{2 , plasma} = {I}_{2 , total} / cos θ$$

Here, the current I_{2,plasma} is the second harmonic wave current generated by the fundamental wave voltage Vₚₗₐₛₘₐ calculated by the above equation. Therefore, the second harmonic wave current I_{2,plasma} has the same phase as the fundamental wave current Iₚₗₐₛₘₐ. Hence, the phase θ represents the phase difference between the fundamental wave current and the second harmonic wave current.

Further, the following equations are satisfied.

$${I}_{2 , total} = {I}_{2 , plasma} + {I}_{2 , cancel}$$

$${I}_{2 , total} ( 1 / i ω {C}_{add} + {R}_{p} ) = ( {I}_{2 , plasma} + {I}_{2 , cancel} ) ( 1 / i ω {C}_{add} + {R}_{p} )$$

$${I}_{2 , total} ( 1 / i ω {C}_{add} + {R}_{p} ) = {I}_{2 , plasma} \times {R}_{p}$$

The current I_{2,total} indicates that the current I_{2,cancel} and the current I_{2,plasma} cancel each other out. Rₚ/(1/iωC_{add}+Rₚ) indicates the cosine of the phase angle θ of the current I_{2,total} with respect to the current I_{2,plasma}, and the current I_{2,plasma} is in phase with the plasma voltage Vₚₗₐₛₘₐ and in phase with the fundamental current I.

As described above, by accurately determining the fundamental current and the second harmonic current, the plasma state (the plasma electron temperature Tₑ and the plasma ion density nᵢ) can be accurately determined.

### (Control of Second Harmonic Current)

In the circuit model of the measurement system for the second harmonic shown in FIG. 9, it has been described under the assumption that the signal generator 82 is not included. In other words, the case where the harmonic voltage components (second harmonic voltage component, third harmonic voltage component, fourth harmonic voltage component, and the like) measured by the voltage measuring part of the monitor device 80 have been described are zero was described.

Here, the signal generator 82 has a signal generating part that generates a small amplitude signal, and an amplifier part that amplifies and outputs the small amplitude signal generated by the signal generating part. The amplifier part may be, for example, an operational amplifier or the like. As a result, the signal generator 82 controls the amplitude of the fundamental wave (first harmonic wave) by the amplifier part.

In addition, by applying a fundamental wave voltage from the signal generator 82 to the plasma, a second harmonic current flows through the circuit due to the nonlinear current generated in the plasma. Therefore, the second harmonic voltage is generated by the resistance component (internal impedance) of the amplifier part of the signal generator 82 and the second harmonic current flowing through the circuit. Hence, the second harmonic voltage is actually measured by the voltage measuring part of the monitor device 80.

Here, the plasma is considered as a pure resistance (with phase difference) 0° and the insulating film has the capacitance component C with the phase difference of 90°, so that it is possible to separately estimate the thickness of the insulating film (capacitance component C) and the state of the plasma (the plasma electron temperature Tₑ and the plasma ion density nᵢ). On the other hand, the amplifier of the signal generator 82 is arranged in series with the plasma, and it is difficult to separate the second harmonic wave voltage in the amplifier from the second harmonic wave voltage of the plasma.

Therefore, the signal generator 82 of the present embodiment superimposes the fundamental wave voltage and a second harmonic wave voltage (i.e., generated second harmonic wave) that cancels the second harmonic wave voltage in the amplifier of the signal generator 82, and applies them to the plasma. Accordingly, it is possible to make the external voltage of the second harmonic wave voltage at the amplifier of the signal generator 82 zero [V], which makes it possible to prevent the nonlinear current (second harmonic wave current) generated in the plasma and an unnecessary second harmonic wave voltage caused by the resistance component of the amplifier from being applied to the plasma. As a result, the plasma state can be measured with high accuracy using the processes shown in FIGS. 6 to 10.

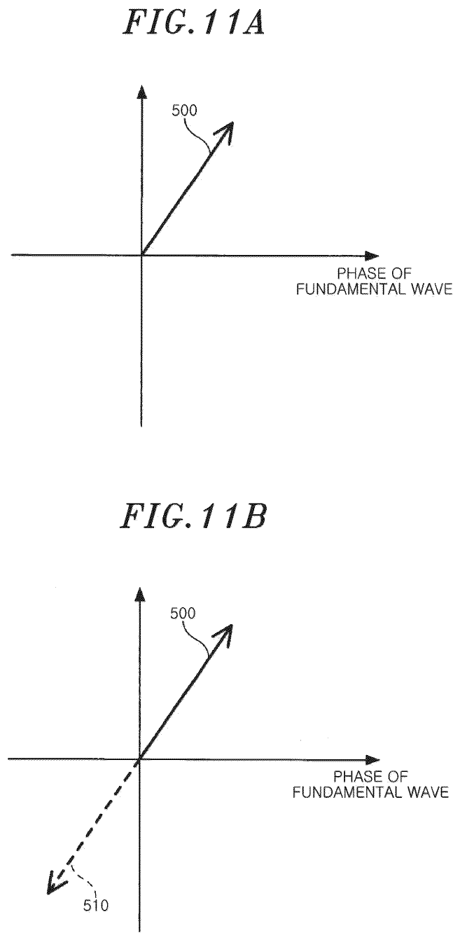

FIGS. 11A and 11B are diagrams showing an example of a voltage vector. As shown in FIG. 11A, a second harmonic wave current generated by the plasma flows through the amplifier, thereby generating a second harmonic wave voltage vector 500. As shown in FIG. 11B, the monitor device 80 controls the signal generator 82 to generate a second harmonic wave voltage vector (generated second harmonic wave) 510 that cancels the second harmonic wave voltage vector 500. Accordingly, it is possible to make the external voltage of the second harmonic wave voltage zero [V].

Here, when the amount of the second harmonic wave current flowing through the amplifier of the signal generator 82 changes, the voltage in the amplifier of the signal generator 82 also changes. Hence, the generated second harmonic wave controls the phase and amplitude by feedback control.

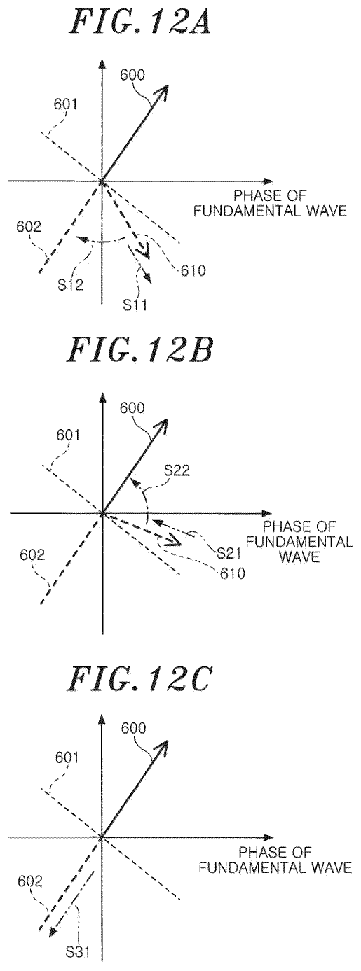

FIGS. 12A to 12C are diagrams showing an example of feedback control. In FIGS. 12A to 12C, a line 601 with a phase difference of ±π/2 [rad] with respect to the detected second harmonic wave 600 is indicated by a thin dashed line. A line 602 with a phase difference of π [rad] with respect to the detected second harmonic wave 600 is indicated by a thick dashed line.

First, the control part 33 performs fast Fourier transform (FFT) analysis on the raw data of the received signal detected by the voltage measuring part of the monitor device 80 (see FIG. 5A) of the analysis part 34. Accordingly, the information on the phase (direction of the vector of the detected second harmonic wave 600) and amplitude (length of the vector of the detected second harmonic wave 600) of the second harmonic wave voltage (detected second harmonic wave 600) is obtained. The detected second harmonic wave 600 corresponds to a composite vector of a voltage vector resulting from the second harmonic wave current flowing from the plasma to the circuit flowing through the resistance component (internal impedance) of the amplifier, and a voltage vector of the second harmonic wave voltage (generated second harmonic wave 610) generated by the signal generator 82.

Further, the control part 33 obtains the information on the phase (direction of the vector of the generated second harmonic wave 610) of the second harmonic wave voltage (generated second harmonic wave 610) generated by the signal generator 82 from the signal generator 82. The phase of the second harmonic wave voltage (generated second harmonic wave 610) is calculated from the fundamental wave phase. Moreover, the control part 33 may obtain the information on the amplitude (length of the vector of the generated second harmonic wave 610) of the second harmonic wave voltage (generated second harmonic wave 610) generated by the signal generator 82 from the signal generator 82. In the control to be described later, the amplitude of the generated second harmonic wave 610 is increased or decreased to set the external voltage of the second harmonic wave voltage to zero [V], and it is not necessary to obtain the information on the amplitude (the vector length of the generated second harmonic wave 610) of the second harmonic wave voltage (generated second harmonic wave 610).

As shown in FIG. 12A, when the phase difference between the detected second harmonic wave 600 and the generated second harmonic wave 610 is π/2 [rad] or more, the voltage (amplitude) of the generated second harmonic wave 610 is increased (arrow S11), and the phase of the generated second harmonic wave 610 is shifted closer toward the direction of the phase of the detected second harmonic wave 600+π [rad] (arrow S12). In other words, the voltage (amplitude) of the generated second harmonic wave 610 is increased, and the phase of the generated second harmonic wave 610 is adjusted in a direction away from the detected second harmonic wave 600 (in a direction in which the phase difference increases). Accordingly, it is possible to reduce the amplitude of the detected second harmonic wave 600 (the length of the vector of the detected second harmonic wave 600).

As shown in FIG. 12B, when the phase difference between the detected second harmonic wave 600 and the generated second harmonic wave 610 is less than π/2 [rad], the voltage (amplitude) of the generated second harmonic wave 610 is reduced (arrow S21), and the phase of the generated second harmonic wave 610 is shifted closer toward the direction of the phase [rad] of the detected second harmonic wave 600 (arrow S22). In other words, the voltage (amplitude) of the generated second harmonic wave 610 is reduced, and the phase of the generated second harmonic wave 610 is adjusted in a direction closer to the detected second harmonic wave 600 (in a direction in which the phase difference decreases). Hence, it is possible to reduce the amplitude of the detected second harmonic wave 600 (the length of the vector of the detected second harmonic wave 600).

As shown in FIG. 12C, when the voltage of the generated second harmonic wave 610 is zero, the phase [rad] of the generated second harmonic wave 610 is set to the phase of the detected second harmonic wave 600+π [rad], and the voltage (amplitude) of the generated second harmonic wave 610 is increased (arrow S31).

Further, when the amplitude of the detected second harmonic wave 600 (the vector length of the detected second harmonic wave 600) does not become sufficiently small even if the voltage (amplitude) of the generated second harmonic wave 610 is reduced in the state shown in FIG. 12B, the voltage of the generated second harmonic wave 610 eventually becomes zero (see FIG. 12C), and the generated second harmonic wave 610 is generated in the opposite direction to the detected second harmonic wave 600. Accordingly, the state shown in FIG. 12A is obtained. Then, by repeating the feedback control, the external voltage of the second harmonic wave voltage at the amplifier of the signal generator 82 can be set to zero [V].

In the examples of FIGS. 12A to 12C, the case where the phase and amplitude of the generated second harmonic wave 610 are simultaneously feedback-controlled has been described. However, the present disclosure is not limited thereto.

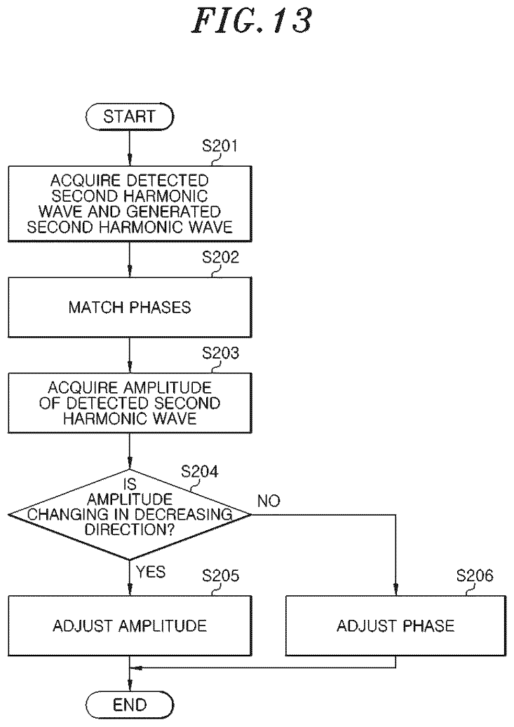

FIG. 13 is a flowchart showing another example of the feedback control.

In step S201, the detected second harmonic wave 600 and the generated second harmonic wave 610 are acquired. Here, the control part 33 acquires at least the phase and amplitude of the detected second harmonic wave 600 and the phase of the generated second harmonic wave 610.

In step S202, the phase of the detected second harmonic wave 600 is aligned with that of the generated second harmonic wave 610. Here, the control part 33 controls the signal generator 82 to adjust the phase of the generated second harmonic wave 610 while maintaining the amplitude of the generated second harmonic wave 610, thereby aligning the phase of the detected second harmonic wave 600 with that of the generated second harmonic wave 610 (reducing the phase difference).

In step S203, the amplitude of the detected second harmonic wave 600 is acquired.

In step S204, it is determined whether the amplitude of the detected second harmonic wave 600 detected in step S203 is changing in a decreasing direction compared to the amplitude of the detected second harmonic wave 600 detected in step S201.

If the amplitude of the detected second harmonic wave 600 is changing in a decreasing direction (S204, YES), the processing of the control part proceeds to step S205. In step S205, the amplitude of the generated second harmonic wave 610 is adjusted.

If the amplitude of the detected second harmonic wave 600 is not changing in a decreasing direction (S204, NO), the processing of the control part proceeds to step S206. In step S206, the phase of the generated second harmonic wave 610 is adjusted.

By repeating the control shown in FIG. 13, the external voltage of the second harmonic wave voltage in the amplifier of the signal generator 82 can be set to zero [V].

While the plasma processing apparatus 100 has been described, the present disclosure is not limited to the above embodiment, and various modifications and improvements can be made without departing from the scope of the appended claims and the gist thereof.

1. A method for controlling a plasma measuring system that measures a state of plasma using a probe device provided in a plasma processing apparatus and a measuring circuit including a signal generator that outputs an AC voltage, the method comprising:
(A) outputting a fundamental wave voltage from the signal generator to the plasma to be measured;
(B) detecting an output terminal AC voltage at an output terminal of the signal generator; and
(C) superimposing a voltage of a harmonic voltage component, which reduces an amplitude of the harmonic voltage component contained in the output terminal AC voltage, on the fundamental wave voltage, and outputting the superimposed voltage from the signal generator.

2. The method for controlling a plasma measuring system of claim 1, wherein the harmonic voltage component is a second harmonic component.

3. The method for controlling a plasma measuring system of claim 2, wherein the harmonic voltage component contained in the output terminal AC voltage is a detected second harmonic wave, and
a voltage of the harmonic voltage component superimposed on the fundamental wave voltage is a generated second harmonic wave.

4. The method for controlling a plasma measuring system of claim 3, wherein when a phase difference between the detected second harmonic wave and the generated second harmonic wave is greater than or equal to π/2 [rad], an amplitude of the generated second harmonic wave is increased, and a phase of the generated second harmonic wave is shifted away from a phase of the detected second harmonic wave.

5. The method for controlling a plasma measuring system of claim 3, wherein when a phase difference between the detected second harmonic wave and the generated second harmonic wave is less than π/2 [rad], an amplitude of the generated second harmonic wave is decreased, and a phase of the generated second harmonic wave is shifted closer to a phase of the detected second harmonic wave.

6. The method for controlling a plasma measuring system of claim 3, wherein when an amplitude of the generated second harmonic wave is zero, a phase of the generated second harmonic wave is set to a phase of the detected second harmonic wave+π [rad], and the amplitude of the generated second harmonic wave is increased.

7. The method for controlling a plasma measuring system of claim 1, wherein the (B) and the (C) are repeated.

8. A plasma measuring system for measuring a state of plasma, comprising:
a probe device provided in a plasma processing apparatus;
a measuring circuit including a signal generator that outputs an AC voltage; and
a control part,
wherein the control part is configured to execute:
(A) outputting a fundamental wave voltage from the signal generator to the plasma to be measured;
(B) detecting an output terminal AC voltage at an output terminal of the signal generator;
(C) superimposing a voltage of a harmonic voltage component, which reduces an amplitude of the harmonic voltage component contained in the output terminal AC voltage, on the fundamental wave voltage and outputting the superimposed voltage from the signal generator.
